(19) United States
(12) Patent Application Publication
(10) Pub. No.: US 2025/0226237 A1
(43) Pub. Date: Jul. 10, 2025

(54) METHOD FOR MOUNTING BONDING MATERIAL DEPOSITS

(71) Applicant: PROTEC CO., LTD., Gyeonggi-do (KR)

(72) Inventors: Youn Sung Ko, Gyeonggi-do (KR); YOSHIAKI YUKIMORI, KANAGAWA (JP); GEUNSIK AHN, Seoul (KR)

(73) Assignee: PROTEC CO., LTD., Gyeonggi-do (KR)

(21) Appl. No.: 19/008,637

(22) Filed: Jan. 3, 2025

(30) Foreign Application Priority Data
Jan. 9, 2024 (KR) 10-2024-0003272

(51) Int. Cl. H01L 21/48; H01L 21/60

(52) U.S. Cl. CPC H01L 21/4853; H01L 21/60; H01L 2021/6027

(57) ABSTRACT

Provided is a method of mounting bonding material deposits, a method of mounting bonding material deposits in mounting recesses formed in a mask so that the bonding material deposits may be mounted on an electrode of a substrate. According to the method of mounting the bonding material deposits, an area of the region where the bonding material deposits are concentrated in the chamber is increased, and thus, small and light-weight conductive balls may be effectively mounted in the mounting recesses of the mask. Also, according to the method of mounting the bonding material deposits, because chances that the bonding material deposits come into contact with the mounting recesses in the mask increase, the bonding material deposits may be rapidly and thoroughly mounted in the plurality of mounting recesses formed in the mask.

### CROSS-REFERENCE TO RELATED APPLICATION

This application is based on and claims priority under 35 U.S.C. § 119 to Korean Patent Application No. 10-2024-0003272, filed on Jan. 9, 2024, in the Korean Intellectual Property Office, the disclosure of which is incorporated by reference herein in its entirety.

### BACKGROUND

### Field

The present disclosure relates to a method of mounting bonding material deposits, and in particular, to a method of mounting bonding material deposits in mounting recesses formed in a mask so that the bonding material deposits may be mounted on an electrode of a substrate.

### Description of Related Art

A conductive ball such as a solder ball may be frequently used for electric connection when a semiconductor apparatus, such as a large-scale integration (LSI), a liquid crystal display (LCD), etc. is mounted.

A conductive ball of a fine particle type having a diameter of 1 mm or less is loaded on a substrate to be used in an electric mounting of the substrate. To this end, a mask having mounting recesses is mainly used. Conductive balls are mounted in mounting recesses formed in a mask while the mask is disposed on a substrate, or conductive balls are mounted in the mounting recesses of the mask separately from the substrate and then are transferred to be attached to the substrate.

Recently, a conductive ball has reduced to a size of tens to hundreds of micrometers and a substrate has been integrated, and thus, the number of conductive balls to be mounted in a unit area also increases.

However, when the size of the conductive ball is reduced and a weight of the conductive ball is also reduced, there may be a difficulty in mounting the conductive balls on the mask in the manner according to the related art.

Japanese Laid-open Patent No. 2010-177230 discloses a ball supply apparatus as shown in FIG. 1. Such above ball supply apparatus is generally referred to as a “cyclone head”. The cyclone head according to the related art has a structure, in which an air flow in the form of a whirlwind-type is formed by fins 28a in a chamber while conductive balls are accommodated in the chamber of a cylindrical shape. However, in the case of the cyclone head according to the related art, when a very fast air flow in the whirlwind-type is generated in the chamber like a tornado, movements of the conductive balls are aroused in a direction parallel to an upper surface of the mask. The mounting recesses of the mask are formed in a vertical direction and the conductive balls mainly move in a horizontal direction, and thus, an efficiency of mounting the conductive balls is not high enough. In particular, when the size and weight of the conductive ball are reduced, a phenomenon that the conductive balls may float upward in the chamber occurs similarly to the tornado or spout. That is, the conductive balls are not moved in the direction toward the mounting recess in the mask located at the lower side, but are moved upward, that is, the opposite direction. It is difficult to efficiently perform the conductive ball mounting process with the cylindrical cyclone head according to the related art.

Also, according to the cyclone head having the cylindrical shape of the related art as shown in FIG. 1, the conductive balls are concentrated at the center of the head, rather than evenly distributed in the head, and thus, a productivity of a conductive ball mounting process on the mask degrades. That is, because an area of an effective region in which the conductive balls are concentrated is relatively small, when an operation of mounting the conductive balls on a mask having a relatively large area is performed, it takes a lot of time to pass through the entire area of the mask with the narrow effective area.

Therefore, a method of effectively loading the bonding material deposits including the conductive balls in the mounting recesses of the mask is necessary. Also, even when bonding material deposits have small size and light weight, a method of rapidly and accurately mounting the bonding material deposits thoroughly in all mounting recesses of the mask is also necessary.

### SUMMARY

The present disclosure provides a method of mounting bonding material deposits, the method being capable of rapidly and accurately mounting small and light-weight conductive balls in all mounting recesses of a mask.

According to an embodiment of the present disclosure, provided is a method of mounting bonding material deposits in mounting recesses formed in a mask, including: (a) arranging the mask horizontally; (b) arranging a mounting head to be adjacent to an upper surface of the mask, the mounting head including: a head body including a first wall member and a second wall member that are arranged to face each other and connected parallel to each other in a horizontal direction, a first connection member and a second connection member connecting opposite ends of the first wall member and the second wall member respectively to each other, a central chamber surrounded by the first wall member and the second wall member and the first connection member and the second connection member so that the bonding material deposits are to stay, and a cover member covering an upper side of the central chamber; a first main nozzle that is formed to extend along a lengthwise direction of the first wall member in a lower portion of the first wall member so as to discharge a compressed gas toward a lower inner portion of the central chamber; and a second main nozzle that is formed by extending in a lengthwise direction of the second wall member in a lower portion of the second wall member so as to discharge a compressed gas to a lower inner portion of the second wall member; (c) supplying the bonding material deposits to an inside of the central chamber of the mounting head; (d) discharging the compressed gas respectively through the first main nozzle and the second main nozzle of the mounting head; and (e) transporting the mounting head in a horizontal direction with respect to the mask while performing step (d) so that the bonding material deposits in the inside of the central chamber of the mounting chamber are mounted in mounting recesses in the mask.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a diagram for describing a structure of a head for mounting conductive balls, according to the related art.

FIG. 2 is a perspective view of a mounting head for implementing a method of mounting bonding material deposits according to an embodiment of the present disclosure.

FIG. 3 is an exploded perspective view of the mounting head of FIG. 2.

FIG. 4 is a cross-sectional view of the mounting head taken along line IV-IV of FIG. 2.

FIG. 5 is a cross-sectional view of the mounting head taken along line V-V of FIG. 2.

FIG. 6 is a perspective view of a mounting head for implementing a method of mounting bonding material deposits according to another embodiment of the present disclosure.

FIG. 7 is an exploded perspective view of the mounting head of FIG. 6.

FIG. 8 is a cross-sectional view of the mounting head taken along line VIII-VIII of FIG. 6.

FIG. 9 is a cross-sectional view of the mounting head taken along IX-IX of FIG. 6.

### DESCRIPTION OF THE EMBODIMENTS

Hereinafter, a method of mounting bonding material deposits according to the present disclosure is described in detail below with reference to accompanying drawings. First, referring to the drawings, a structure of a mounting head used to implement the method of mounting the bonding material deposits according to the present disclosure is described.

The present disclosure is to mount bonding material deposits (or connecting material deposits) such as conductive balls in mounting recesses of a mask. Hereinafter, an example in which conductive balls are mounted in a mask as an example of the bonding material deposits is described below, but the bonding material deposits are not limited to the conductive balls, and other various connecting elements used to connect a chip to an electrode of a substrate, such as copper pillars, copper pins, etc. may be used.

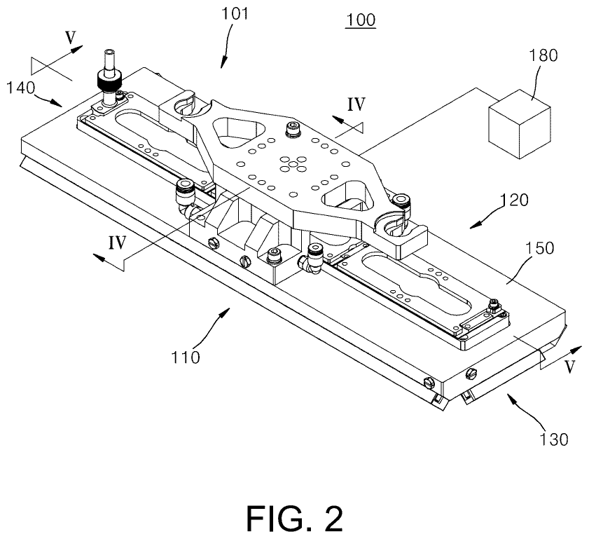

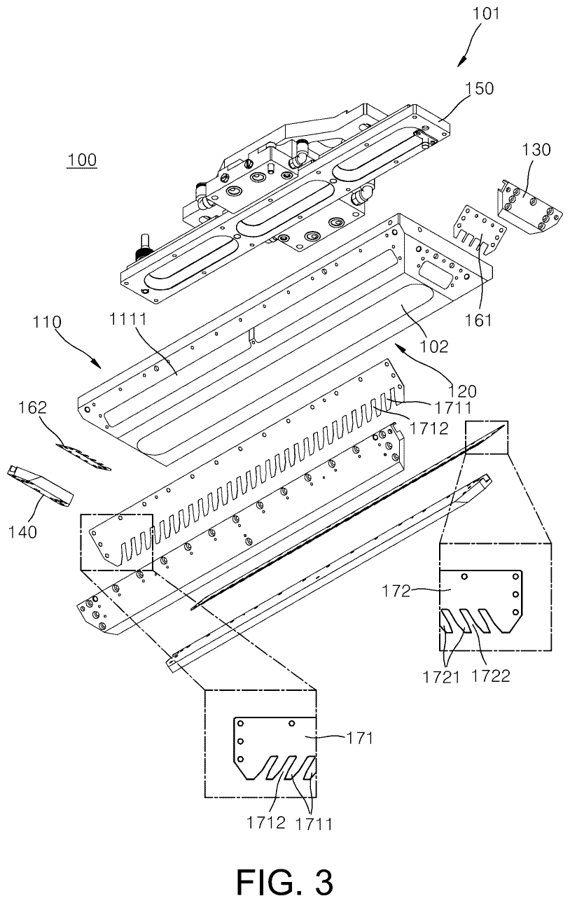

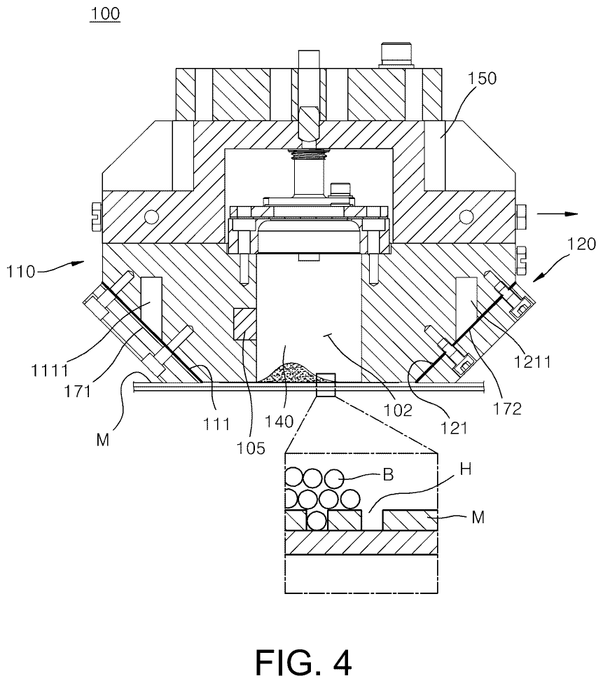

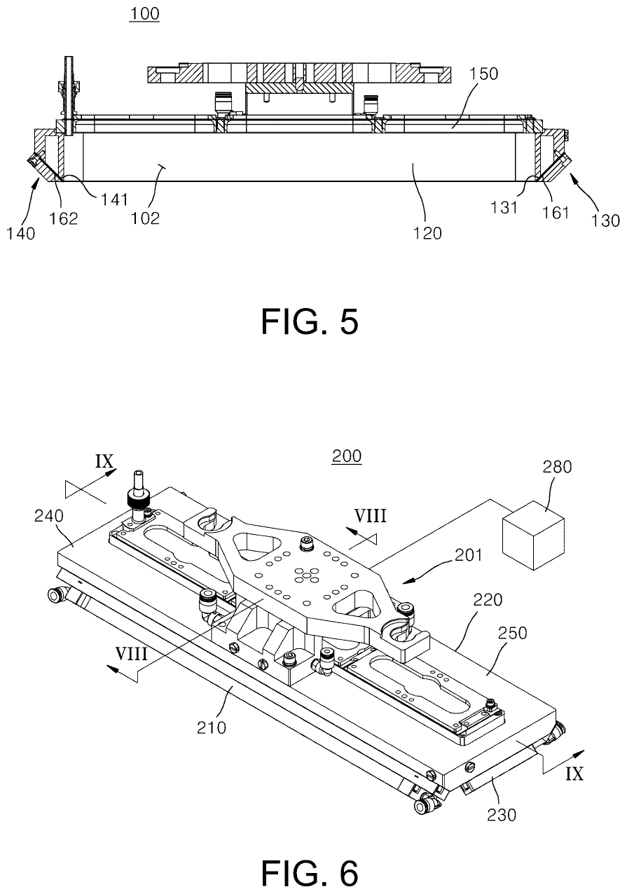

FIG. 2 is a perspective view of a mounting head for implementing the method of mounting the bonding material deposits according to an embodiment of the present disclosure, FIG. 3 is an exploded perspective view of the mounting head of FIG. 2, FIG. 4 is a cross-sectional view of the mounting head taken along line IV-IV of FIG. 2, and FIG. 5 is a cross-sectional view of the mounting head taken along line V-V of FIG. 2.

Referring to FIGS. 2 to 5, a mounting head 100 used to implement the method of mounting the bonding material deposits according to the embodiment includes a head body 101, a first main nozzle 111, and a second main nozzle 121.

The head body 101 includes a first wall member 110, a second wall member 120, a first connection member 130, a second connection member 140, a central chamber 102, and a cover member 150.

The first wall member 110, the second wall member 120, the first connection member 130, and the second connection member 140 are connected to one another to form an outer circumference surrounding the central chamber 102, and the cover member 150 may be formed to cover an upper portion of the central chamber 102. Conductive balls B for being mounted in mounting recesses H of a mask M are accommodated and stay in the central chamber 102.

The first wall member 110 and the second wall member 120 are arranged to face each other and are formed to extend in parallel to each other in a horizontal direction. The first connection member 130 and the second connection member 140 may respectively connect both ends of the first wall member 110 to both ends of the second wall member 120.

The first main nozzle 111 is formed to extend along the lengthwise direction of the first wall member 110 on the lower portion of the first wall member 110, so as to discharge a compressed gas to the lower side in the central chamber 102. In the embodiment, the first main nozzle 111 is formed to be in communication with the lower surface of the first wall member 110.

The second main nozzle 121 is formed to extend along the lengthwise direction of the second wall member 120 on the lower portion of the second wall member 120, so as to discharge the compressed gas to the lower side in the central chamber 102. In the embodiment, the second main nozzle 121 is formed to be in communication with the lower surface of the second wall member 120, so that the compressed gas may be discharged to the boundary between the lower surface and the inner wall surface of the second wall member 120.

Referring to FIG. 4, the first main nozzle 111 is formed to be inclined in a direction closer to the central chamber 102, toward the lower side of the first wall member 110. Due to the inclined structure of the first main nozzle 111, the conductive balls B that are adjacent to the inner wall of the first wall member 110 are guided to move in a direction away from the first wall member 110 (that is, toward the central chamber 102).

Like the first main nozzle 111, the second main nozzle 121 is also formed to be inclined in a direction closer to the central chamber 102, toward the lower side of the second wall member 120.

In the embodiment, the first main nozzle 111 and the second main nozzle 121 are formed to be inclined in opposite directions, and inclined angles of the first main nozzle 111 and the second main nozzle 121 with respect to the first wall member 110 and the second wall member 120 are the same as each other.

A plurality of first guide recesses 1712 and a plurality of second guide recesses 1722 are formed in the first main nozzle 111 and the second main nozzle 121, respectively. The first guide recesses 1712 and the second guide recesses 1722 guide discharging directions of the compressed gas discharged respectively from the first main nozzle 111 and the second main nozzle 121. In the embodiment, the first guide recesses 1712 and the second guide recesses 1722 are respectively formed to be arranged at certain intervals along the directions in which the first wall member 110 and the second wall member 120 extend.

Also, in the embodiment, the plurality of first guide recesses 1712 and second guide recesses 1722 are respectively formed by a first guide member 171 and a second guide member 172 that are respectively arranged in the first main nozzle 111 and the second main nozzle 121. The first guide member 171 and the second guide member 172 respectively include a plurality of first guide pins 1711 and a plurality of second guide pins 1721. The first guide recesses 1712 are formed between the plurality of first guide pins 1711, and the second guide recesses 1722 are formed between the plurality of second guide pins 1721.

The plurality of first guide pins 1711 are formed to be inclined so as to extend in the direction in which the first wall member 110 extends (lengthwise direction), toward the lower side of the first wall member 110, and the plurality of second guide pins 1721 are formed to be inclined so as to extend in the direction in which the second wall member 120 extends (lengthwise direction), toward the lower side of the second wall member 120. Due to the first guide pins 1711 and the second guide pins 1721, the compressed gas discharged from each of the first main nozzle 111 and the second main nozzle 121 is discharged in a direction that is inclined, not perpendicular to, with respect to the lengthwise direction of the first wall member 110 and the second wall member 120.

In the embodiment, the plurality of first guide recesses 1712 and the plurality of second guide recesses 1722 formed by the first guide pins 1711 and the second guide pins 1721 are formed to be inclined in opposite directions to each other as shown in FIG. 3, and the inclined angles thereof are the same as each other.

In addition, the first wall member 110 and the second wall member 120 have a first flow path 1111 and a second flow path 1211 formed therein, and the first flow path 1111 and the second flow path 1211 are respectively connected to the first main nozzle 111 and the second main nozzle 121. A pressure of the compressed gas supplied to the first flow path 1111 and the second flow path 1211 is controlled by a controller 180. In the embodiment, the controller 180 controls the compressed gas supplied to the first flow path 1111 and the compressed gas supplied to the second flow path 1211 to have different pressures from each other. That is, the controller 180 maintains the pressure of the compressed gas supplied to the first flow path 1111 to be greater than that of the compressed gas supplied to the second flow path 1211.

The first connection member 130 and the second connection member 140 connecting the first wall member 110 to the second wall member 120 also respectively have a first connection main nozzle 131 and a second connection main nozzle 141. Like the first main nozzle 111 and the second main nozzle 121 described above, the first connection main nozzle 131 and the second connection main nozzle 141 respectively extend on the lower portions of the first connection member 130 and the second connection member 140 along the directions in which the first connection member 130 and the second connection member 140 extend, so that the compressed gas may be discharged respectively to the lower side in the first connection member 130 and the second connection member 140. Also, the first connection main nozzle 131 and the second connection main nozzle 141 are formed to be inclined in the direction closer to the central chamber 102, toward the lower portions of the first connection member 130 and the second connection member 140, respectively.

The first connection main nozzle 131 and the second connection main nozzle 141 may be formed to be connected or not to be connected to the first main nozzle 111 and the second main nozzle 121.

Referring to FIG. 3, a first connection guide member 161 and a second connection guide member 162 are arranged in the first connection main nozzle 131 and the second connection main nozzle 141, and the first connection guide member 161 and the second connection guide member 162 are formed similarly to the first guide member 171 and the second guide member 172 described above.

The first connection member 130 and the second connection member 140 respectively have concavely curved inner wall surfaces that come into contact with the central chamber 102, as shown in FIG. 3.

The controller 180 constantly maintains the pressure of the compressed gas supplied to the first connection main nozzle 131 and the second connection main nozzle 141.

An ionizer 105 may be installed on an inner wall surface of a component such as the central chamber 102, the first wall member 110, and the second wall member 120, etc., or on the flow path of the compressed gas. When the process of mounting conductive balls B is performed by using the conductive balls B having very small sizes and light weight, the conductive balls B may stick to the components such as the inner wall surface of the central chamber or the mask M due to static electricity. Here, when the controller 180 described above may operate the ionizer 105 to remove the static electricity, the quality and productivity in the conductive ball mounting process may be improved.

Hereinafter, processes of implementing the method of mounting the bonding material deposits according to the present disclosure by using the mounting head 100 configured as above are described below.

First, the mask M having the mounting recesses H formed therein for mounting the conductive balls B is arranged horizontally (step (a)). Here, a substrate may be arranged under the mask M or a conductive ball holder such as a suction plate may be arranged under the mask M. When the substrate is arranged under the mask M, the conductive balls B are directly mounted on the substrate via the mounting recesses H of the mask M. When the conductive ball holder is arranged under the mask M, the conductive balls B mounted in the mounting recesses H may be transferred to the conductive ball holder, and after that, are transferred to the substrate and then bonded.

Next, the mounting head 100 configured as described above is arranged to be closer to an upper surface of the mask M (step (b)).

In the above state, the conductive balls B are supplied into the central chamber of the mounting head 100 and stored (step (c)).

Next, the controller 180 controls the compressed gas to be supplied constantly at a set pressure respectively to the first main nozzle 111, the second main nozzle 121, the first connection main nozzle 131, and the second connection main nozzle 141, by using a mechanical component such as a pneumatic regulator (step (d)). The compressed gas may include air or nitrogen gas. Other gases than the air and the nitrogen gas may be supplied through the nozzles.

Here, as described above, the controller 180 may maintain the pressure of the compressed gas supplied to the first flow path 1111 and the pressure of the compressed gas supplied to the second flow path 1211 to be equal to each other or the pressure of the first flow path 1111 and the pressure of the second flow path 1211 to be different from each other. In general, the controller 180 maintains the pressures of the first flow path 1111 and the second flow path 1211 to be different from each other. Also, the controller 180 may maintain the pressures of the first flow path 1111 and the second flow path 1211 constantly over time, or may adjust the pressures of the first flow path 1111 and the second flow path 1211 to be changed in certain patterns over time such as a sine wave or a pulse wave.

As described above, the first main nozzle 111, the second main nozzle 121, the first connection main nozzle 131, and the second connection main nozzle 141 are formed to be inclined in the direction closer to the central chamber 102 toward the lower sides thereof, and thus, the compressed gas discharged from each nozzle forms a flow of the gas toward the central chamber 102. That is, when the mounting head 100 according to the embodiment is arranged to be adjacent to the mask M, the gas flow is generated between the mask M and the lower surface of the mounting head 100, and thus, the gas flow is generated toward the inside of the central chamber 102 between the lower surface of each of the first wall member 110, the second wall member 120, the first connection member 130, and the second connection member 140 and the mask M. Due to the flow of gas as described above, the conductive balls B in the central chamber 102 stay in the central chamber 102 without leaking to the outside of the central chamber 102.

Because the first wall member 110 and the second wall member 120 are arranged parallel to each other and extend in the lengthwise direction and the compressed gases are respectively discharged from the first main nozzle 111 and the second main nozzle 121 in the lengthwise direction with the uniform pressure, the conductive balls B may be evenly distributed in the central chamber 102 along the lengthwise direction of the central chamber 102. That is, the conductive balls B are distributed in the form of a line extending lengthily in the central chamber 102.

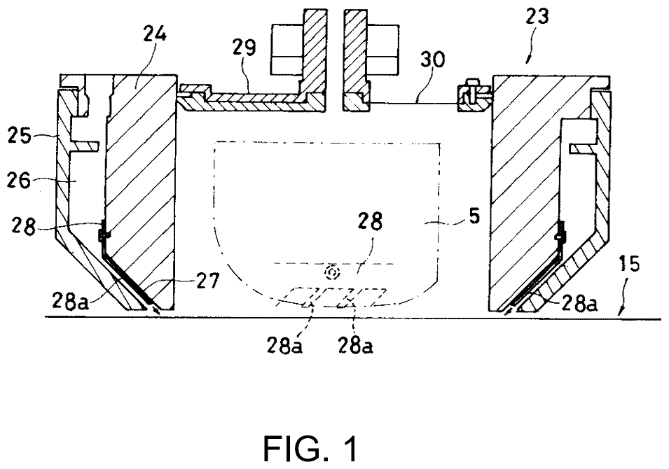

In this state, the mounting head 100 is horizontally transported in a direction perpendicular to the first wall member 110 and the second wall member 120 (step (e)). The above process is performed by a separate transport unit for horizontally transporting the mounting head 100. The conductive balls B are lengthily arranged in the central chamber 102 in a direction in which the central chamber 102 extends. In the above state, when the mounting head 100 is horizontally transported, the process of mounting the conductive balls B is performed while covering the upper surface of the mask M of a relatively large area. As described above, the mounting head 100 lengthily extends in a rectangular shape, and thus, the conductive balls B may be mounted rapidly and effectively in all of the mounting recesses H without omission with respect to the upper surface of the mask M of a relatively large area. As described above, the method of mounting the bonding material deposits of the present disclosure may have noticeably improved productivity as compared with the method of using the cyclone head as shown in FIG. 1 according to the related art.

Also, as described above, the pressure in the first main nozzle 111 and the pressure in the second main nozzle 121 are set to be different from each other, that is, when the controller 180 maintains the pressure in one of the first main nozzle 111 and the second main nozzle 121 to be greater than the other, the flow of gas capable of further improving the efficiency of mounting the conductive balls B is generated in the central chamber 102. For example, when the pressure in the first main nozzle 111 is greater than that of the second main nozzle 121, in the lower portion in the central chamber 102, the flow of gas moving in the direction from the first wall member 110 to the second wall member 120 is generated. As described above, the flow of gas moving toward the second wall member 120 in the lower portion of the central chamber 102 collides with the inner wall of the second wall member 120 and rises upward, and then, is moved toward the inner wall of the first wall member 110 along the cover member 150 in the upper portion of the central chamber 102. As described above, the flow of gas that collides with the first wall member 110 while moving toward the first wall member 110 in the upper portion of the central chamber 102 is moved downward after colliding with the inner wall of the first wall member 110. When the above processes continuously occur, the flow of gas that circulates about a virtual rotary shaft at a high velocity is generated in the central chamber 102, wherein the virtual rotary shaft extends in the direction parallel to the direction in which the first wall member 110 and the second wall member 120 extend (that is, horizontal direction). Accordingly, at the vicinity of the first wall member 110, the flow of gas strongly descending along the inner wall surface of the first wall member 110 (that is, the downdraft) is generated, and thus, a probability that the conductive balls B are seated in the mounting recesses H of the mask M while descending along with the flow of gas is greatly increased. Also, the conductive balls B descending at the vicinity of the first wall member 110 flow in the direction toward the second wall member 120 while being in close contact with the surface of the mask M, and thus, during the process, the probability that the conductive balls are seated in the mounting recesses H of the mask M also increases.

In the cyclone head described above with reference to FIG. 1 according to the related art, the flow of gas circulating about the rotary shaft extending in the vertical direction along the inner wall surface of the chamber formed in a cylindrical shape is generated, and thus, the actual efficiency of mounting the conductive balls B in the mounting recesses H of the mask M degrades as compared with the embodiment of the disclosure. That is, in the cyclone head described above with reference to FIG. 1 according to the related art, it is difficult to form the flow of conductive balls B moving nearly in the perpendicular angle toward the surface of the mask M.

However, according to the present disclosure, the flow of gas in which the conductive balls B move head-on toward the mask M or the mounting recesses His effectively generated, and thus, the productivity of the conductive ball mounting process may be greatly improved. In particular, the mounting head 100 is configured in a shape extending in the lengthwise direction, and accordingly, a large area of the mask M may be covered while a volume of the mounting head 100 itself is not much different from that of the related art. As such, the method of mounting the bonding material deposits according to the present disclosure may easily reduce the time duration taken to perform the conductive ball mounting process.

In addition, as described above, when the mounting head 100 is configured so that the compressed gas discharged from the first main nozzle 111 and the second main nozzle 121 may be discharged in the direction inclined with respect to the inner wall surfaces of the first wall member 110 and the second wall member 120 by the first guide member 171 and the second guide member 172, the performance of mounting the conductive balls B may be improved in another way.

In the above case, the flow of gas moving from the first wall member 110 toward the second wall member 120 in the lower portion of the central chamber 102 is formed in a diagonal direction that is inclined toward the direction in which the first wall member 110 extends. The flow of gas formed by the above passage increases a probability that the conductive balls B come into contact with the upper surface of the mask M. When crossing between the first wall surface and the second wall surface in an inclined direction, rather than in the perpendicular direction, a distance through which the conductive balls B pass on the upper surface of the mask M increases. Accordingly, the probability that the conductive balls B would come into contact with the upper surface of the mask M increases, and thus the probability of mounting the conductive balls B in the mounting recesses H also increases. Also, even when the pressure in the first main nozzle 111 and the pressure in the second main nozzle 121 are not uniform due to a certain factor along the lengthwise directions of the first wall member 110 and the second wall member 120, as shown in FIG. 3, the distribution of conductive balls B in the central chamber 102 may be induced to be relatively uniform in the lengthwise direction thereof, due to the flow of gas in the diagonal direction formed by the first guide recesses 1712 and the second guide recesses 1722. According to the above method, the probability that the conductive balls B would not be mounted in the mounting recesses H in a certain region of the mask M through which the mounting head 100 passes may be reduced. Also, when the flow of conductive balls B in the diagonal direction is formed in the central chamber 102 due to the first guide recesses 1712 and the second guide recesses 1722, the flow of gas descending along the inner wall surface of the first wall member 110 is still maintained, and thus, the mounting efficiency is improved as the conductive balls B are moved head-on toward the mounting recesses H due to the flow of gas.

In addition, the method of mounting the bonding material deposits according to the present disclosure may be implemented in the manner of setting the pressures in the first main nozzle 111 and the second main nozzle 121 to be different from each other according to the direction in which the mounting head 100 is horizontally transported. For example, when the mounting head 100 is horizontally transported to a right side based on FIG. 4, the method of mounting the bonding material deposits may be implemented in the manner that the pressure in the second main nozzle 121 is set to be greater than that of the first main nozzle 111. In this case, the conductive balls B are concentrated toward the rear portion with respect to the direction of transporting the mounting head 100, and then, a density of the conductive balls B is increased at a side adjacent to the first main nozzle 111. As described above, as the density of the conductive balls B in a certain region is increased, the efficiency of mounting the conductive balls B may be improved. On the contrary, when the mounting head 100 is horizontally transported to a left side based on FIG. 4, the method of mounting the bonding material deposits may be implemented in the manner that the pressure in the first main nozzle 111 is set to be greater than that of the second main nozzle 121.

Also, when the conductive balls B are very small in size, the step (d) may be implemented so that the compressed gas supplied to the first main nozzle 111 and the second main nozzle 121 is discharged with the pressure in the form of a pulse wave. When the conductive balls B are very tiny in sizes, the weight of the conductive balls B is also very small, and the conductive balls B may lift and float even with a very weak air flow. In this case, when the compressed gas is supplied to the first main nozzle 111 and the second main nozzle 121 in the form of the pulse wave, the conductive balls B fall downward and come into contact with the surface of the mask M when the pressure is instantly lowered, and accordingly, the probability that the conductive balls B are mounted in the mounting recesses H increases.

Also, the order of the step (c) in which the conductive balls B are supplied to the central chamber and the step (b) in which the mounting head is arranged adjacent to the upper surface of the mask M may be switched, and the step (c) may be performed while performing the step (d) or step (e).

The method of mounting the bonding material deposits according to the present disclosure and the example of the mounting head 100 for implementing the method are described as above, but the mounting head used in the present disclosure is not limited to the example described above.

For example, in the above description, the first guide pins 1711 and the second guide pins 1721 are formed to be inclined with respect to the direction in which the first wall member 110 and the second wall member 120 extend, but the first guide pins and the second guide pins may be formed in the direction perpendicular to the direction in which the first wall member and the second wall member extend, respectively. In this case, the first guide recesses and the second guide recesses formed by the first guide pins and the second guide pins are also formed in the direction perpendicular to the direction in which the first wall member and the second wall member extend.

Also, in the above description, the first guide recesses 1712 and the second guide recesses 1722 are formed respectively by the first guide member 171 and the second guide member 172, but the first guide recesses and the second guide recesses may be formed without using the first guide member 171 and the second guide member 172. That is, concavo-convex patterns may be respectively formed on the inner wall surfaces of the first main nozzle and the second main nozzle to generate the first guide recesses and the second guide recesses.

In some cases, a mounting head having a structure in which the first guide recesses 1712 and the second guide recesses 1722 are not provided may be used to implement the method of mounting the bonding material deposits.

Also, structures and shapes of the first guide recesses and the second guide recesses or the first guide member and the second guide member may be variously modified, in addition to the above-described structures.

Also, in the above description, the first main nozzle 111 and the second main nozzle 121 are formed to be inclined in the direction closer to the central chamber 102 toward the lower portions thereof, but the structures of the first main nozzle and the second main nozzle are not limited thereto. A mounting head that is configured so that the directions of the compressed gas discharged from the first main nozzle and the second main nozzle may be adjusted by using a separate structure, rather than the inclined structures of the first main nozzle and the second main nozzle, may be used.

Also, in the above description, the first main nozzle 111 and the second main nozzle 121 are formed to be in communication with the lower surfaces of the first wall member 110 and the second wall member 120, respectively. However, in some cases, the method of mounting the bonding material deposits may be implemented by using a mounting head having a structure in which the first main nozzle and the second main nozzle are formed to be in communication with the wall surfaces of the first and second wall members at the central chamber side. In the above structure, the flow of conductive balls B rapidly descending between the first wall member and the second member toward the mask M may be generated as described above. Also, a mounting head having a structure in which the first main nozzle and the second main nozzle are formed to be respectively in communication with boundaries between the lower surfaces and the inner wall surfaces of the first wall member and the second wall member, may be used.

Also, the inclined angle of the first main nozzle with respect to the first wall member and the inclined angle of the second main nozzle with respect to the second wall member may be formed to be different from each other. As described above, descending movement of the conductive balls B due to the rotation of the compressed gas in the central chamber may be induced by configuring different inclined angles of the first main nozzle and the second main nozzle. In particular, when the first main nozzle and the second main nozzle are configured to have different inclined angles, the various types of airflow may be formed in the central chamber even when the controller controls the compressed gases supplied to the first main nozzle and the second main nozzle to have the same pressure.

Also, in the above description, the first connection guide member 161 and the second connection guide member 162 that are formed similarly to the first guide member 171 and the second guide member 172 are arranged in the first connection main nozzle 131 and the second connection main nozzle 141, but a mounting head having a structure in which the first connection guide member 161 and the second connection guide member 162 are not provided may be used. Also, a mounting head including a first connection guide member and a second connection guide member having different structures from those shown in the drawings, may be used.

Next, referring to FIGS. 6 to 9, a mounting head 200 according to another embodiment for implementing the method of mounting the bonding material deposits according to the present disclosure is described below.

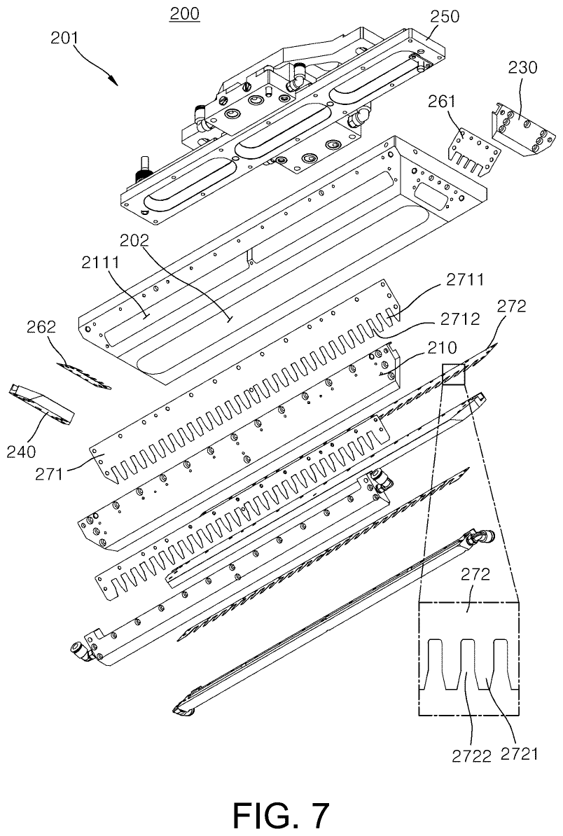

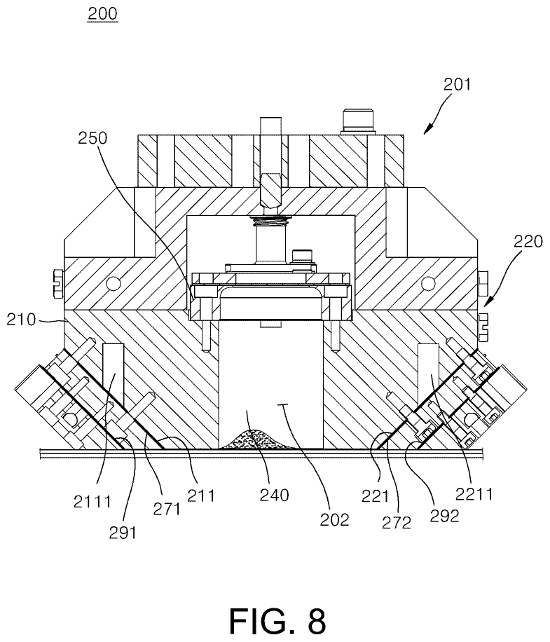

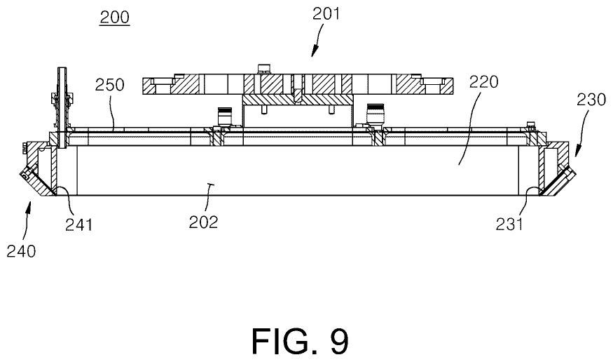

FIG. 6 is a perspective view of a mounting head for implementing the method of mounting the bonding material deposits according to another embodiment of the present disclosure, FIG. 7 is an exploded perspective view of the mounting head of FIG. 6, FIG. 8 is a cross-sectional view of the mounting head taken along line VIII-VIII of FIG. 6, and FIG. 9 is a cross-sectional view of the mounting head taken along line IX-IX of FIG. 6.

Referring to FIGS. 6 to 9, the mounting head 200 according to another embodiment includes a head body 201, a first main nozzle 211, and a second main nozzle 221 like in the mounting head 100 of the embodiment described above with reference to FIGS. 2 to 5, wherein the head body 201 includes a first wall member 210, a second wall member 220, a first connection member 230, a second connection member 240, a central chamber 202, and a cover member 250. Also, the mounting head 200 according to the embodiment further includes the first connection member 230 and the second connection member 240. Hereinafter, descriptions about like components as those of the mounting head 100 described above with reference to FIGS. 2 to 5 are omitted, and instead, different reference numerals are added.

The mounting head 200 according to the embodiment includes a first outer nozzle 291 and a second outer nozzle 292 respectively on the outside of the first main nozzle 211 and the outside of the second main nozzle 221.

The first outer nozzle 291 is formed to extend along the lengthwise direction of the first wall member 210 on the lower portion of the first wall member 210. The first outer nozzle 291 is arranged outside the first main nozzle 211. The first outer nozzle 291 is formed to be in communication with the lower surface of the first wall member 210. Through the above structure, the first outer nozzle 291 may discharge the compressed gas toward the lower side of the first wall member 210.

The second outer nozzle 292 is formed to extend in a lengthwise direction of the second wall member 220 on the lower portion of the second wall member 220. The second outer nozzle 292 is arranged outside the second main nozzle 221. The second outer nozzle 292 is formed to be in communication with the lower surface of the second wall member 220. Due to the above structure, the second outer nozzle 292 may discharge the compressed gas toward the lower side of the second wall member 220.

Also, the first outer nozzle 291 is formed to be inclined in a direction closer to the central chamber 202, toward the lower side of the first wall member 210, like the first main nozzle 211. The second outer nozzle 292 is formed to be inclined in a direction closer to the central chamber 202, toward the lower side of the second wall member 220, like the second main nozzle 221.

The first outer nozzle 291 and the second outer nozzle 292 assist the first main nozzle 211 and the second main nozzle 221, respectively. A flow of gas is formed from the outside to the inside of the central chamber 202 through a gap between the head body 201 and the mask M. Due to the compressed gas discharged from the first outer nozzle 291 and the second outer nozzle 292, the conductive balls B in the central chamber 202 are prevented from leaking to the outside of the central chamber 202. Also, in some cases, the compressed gas discharged from the first outer nozzle 291 and the second outer nozzle 292 assists the pressure of the compressed gas discharged from the first main nozzle 211 and the second main nozzle 221 with the inducing of the flow of the conductive balls B of a sufficient velocity in the central chamber 202.

Also, in some cases, a mounting head, in which the first outer nozzle 291 and the second outer nozzle 292 are formed to be inclined as described above and the first main nozzle and the second main nozzle are formed in the vertical direction, may be implemented. In this case, the compressed gas discharged perpendicularly down from the first main nozzle and the second main nozzle naturally flows into the central chamber 202 due to the compressed gas flowing slantly from the first outer nozzle and the second outer nozzle.

The controller 280 may perform the step (d) and the step (e) while adjusting the pressure in the first main nozzle 211 and the pressure in the second main nozzle 221 in various methods as described above. Here, the controller 280 may maintain the pressures in the first outer nozzle 291 and the second outer nozzle 292 to be equal to each other, or to be different from each other.

Also, the controller 280 may induce the gas flow in the central chamber 202 by maintaining the pressure in the first outer nozzle 291 to be greater than that of the second outer nozzle 292 and the pressure in the first main nozzle 211 to be equal to that of the second main nozzle 221.

Also, in the embodiment, as shown in FIG. 8, an inclined angle of the first outer nozzle 291 with respect to the first wall member 210 and an inclined angle of the second outer nozzle 292 with respect to the second wall member 220 may be equal to each other, or may be set to be different from each other so as to induce the change in the gas flow in the central chamber 202.

Also, in the embodiment, as shown in FIG. 7, a first guide member 271 and a second guide member 272 respectively include a plurality of first guide pins 2711 and a plurality of second guide pins 2721. A plurality of first guide recesses 2712 and a plurality of second guide recesses 2722 are formed by the first guide member 271 and the second guide member 272 arranged in the first main nozzle 211 and the second main nozzle 221, respectively. In the embodiment, unlike the mounting head described above with reference to FIGS. 2 to 5, the plurality of first guide pins 2711 and the plurality of second guide pins 2721 extend in a direction perpendicular to the direction, in which the first wall member 210 and the second wall member 220 extend, toward the lower sides thereof. As described above, the direction in which the plurality of first guide pins 2711 and the plurality of second guide pins 2721 extend may be variously modified as necessary.

The mounting head 200 according to the embodiment may be variously modified like the mounting head 100 described above with reference to FIGS. 2 to 5.

According to the method of mounting the bonding material deposits of the present disclosure, an area of the region where the bonding material deposits are concentrated in the chamber is increased, and thus, small and light-weight conductive balls may be effectively mounted in the mounting recesses of the mask.

Also, according to the method of mounting the bonding material deposits of the present disclosure, because chances that the bonding material deposits come into contact with the mounting recesses in the mask increase, the bonding material deposits may be rapidly and thoroughly mounted in the plurality of mounting recesses formed in the mask.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A method of mounting bonding material deposits in mounting recesses formed in a mask, the method comprising:
a step (a): arranging the mask horizontally;
a step (b): arranging a mounting head to be adjacent to an upper surface of the mask, the mounting head including: a head body including a first wall member and a second wall member arranged to face each other and horizontally extending in parallel with each other, a first connection member and a second connection member connecting opposite ends of the first wall member and the second wall member, a central chamber surrounded by the first wall member and the second wall member and the first connection member and the second connection member so that the bonding material deposits stay therein, and a cover member covering an upper side of the central chamber; a first main nozzle extending in a lengthwise direction of the first wall member on a lower portion of the first wall member so as to discharge compressed gas toward an inner lower portion of the central chamber; and a second main nozzle extending in a lengthwise direction of the second wall member on a lower portion of the second wall member so as to discharge the compressed gas toward an inner lower portion of the second wall member;
a step (c) supplying the bonding material deposits into the central chamber of the mounting head;
a step (d) discharging the compressed gas respectively through the first main nozzle and the second main nozzle of the mounting head; and
a step (e) transporting the mounting head horizontally with respect to the mask while performing the step (d) so that the bonding material deposits in the central chamber of the mounting head are mounted in the mounting recesses of the mask.

2. The method of claim 1, wherein
the first main nozzle is formed to be inclined in a direction closer to the central chamber toward a lower side of the first wall member, and the second main nozzle is formed to be inclined in a direction closer to the central chamber toward a lower side of the second wall member.

3. The method of claim 2, wherein
the first main nozzle is formed to be in communication with a lower surface of the first wall member and the second main nozzle is formed to be in communication with a lower surface of the second wall member.

4. The method of claim 2, wherein
the first main nozzle is formed to be in communication with a wall surface, at a side of the central chamber, of the first wall member and the second main nozzle is formed to be in communication with a wall surface, at the side of the central chamber, of the second wall member.

5. The method of claim 2, wherein
an inclined angle of the first main nozzle with respect to the first wall member is different from an inclined angle of the second main nozzle with respect to the second wall member.

6. The method of claim 1, wherein
the first main nozzle includes a plurality of first guide recesses arranged in a direction in which the first wall member extends so as to guide a discharge direction of the compressed gas, and the second main nozzle includes a plurality of second guide recesses arranged in a direction in which the second wall member extends so as to guide a discharge direction of the compressed gas.

7. The method of claim 6, wherein
the plurality of first guide recesses of the first main nozzle are formed to be inclined so as to extend in the direction in which the first wall member extends toward a lower side, and the plurality of second guide recesses of the second main nozzle are formed to be inclined so as to extend in the direction in which the second wall member extends toward a lower side.

8. The method of claim 7, wherein
the plurality of first guide recesses of the first main nozzle and the plurality of second guide recesses of the second main nozzle are formed to be inclined in opposite directions to each other.

9. The method of claim 1, wherein
the step (d) comprises:
discharging the compressed gas by independently adjusting a pressure of the compressed gas supplied to each of the first main nozzle and the second main nozzle of the mounting head.

10. The method of claim 9, wherein
the step (d) comprises:
discharging the compressed gas supplied to the first main nozzle and the second main nozzle of the mounting head with different pressures.

11. The method of claim 10, wherein
in the step (e), the mounting head is transported in a direction perpendicular to the first wall member and the second wall member, and
in the step (d), the compressed gas is discharged while maintaining a pressure of a nozzle, from among the first main nozzle and the second main nozzle, located in a front portion of a direction in which the mounting head is transported to be greater than a pressure of a nozzle, from among the first main nozzle and the second main nozzle, located in a rear portion of the direction in which the mounting head is transported.

12. The method of claim 9, wherein
the step (d) comprises:
discharging the compressed gas supplied to the first main nozzle and the second main nozzle of the mounting head in a form of a pulse wave.

13. The method of claim 9, wherein
the first main nozzle includes a plurality of first guide recesses arranged in a direction in which the first wall member extends so as to guide a discharge direction of the compressed gas, and the second main nozzle includes a plurality of second guide recesses arranged in a direction in which the second wall member extends so as to guide a discharge direction of the compressed gas.

14. The method of claim 13, wherein
the plurality of first guide recesses of the first main nozzle are formed to be inclined so as to extend in the direction in which the first wall member extends toward a lower side, and the plurality of second guide recesses of the second main nozzle are formed to be inclined so as to extend in the direction in which the second wall member extends toward a lower side.

15. The method of claim 14, wherein
the plurality of first guide recesses of the first main nozzle and the plurality of second guide recesses of the second main nozzle are formed to be inclined in opposite directions to each other.

16. The method of claim 1, wherein the mounting head further includes:
a first outer nozzle formed to extend in the lengthwise direction of the first wall member on the lower portion of the first wall member, at an outside of the first main nozzle, so as to discharge the compressed gas to the lower side of the first wall member; and
a second outer nozzle formed to extend in the lengthwise direction of the second wall member on the lower portion of the second wall member, at an outside of the second main nozzle, so as to discharge the compressed gas to the lower side of the second wall member.

17. The method of claim 16, wherein
the first outer nozzle is formed to be in communication with a lower surface of the first wall member, and
the second outer nozzle is formed to be in communication with a lower surface of the second wall member.

18. The method of claim 16, wherein
the step (d) comprises:
discharging the compressed gas by controlling independently the pressure of the compressed gas supplied to each of the first main nozzle, the second main nozzle, the first outer nozzle, and the second outer nozzle of the mounting head.

19. The method of claim 18, wherein
the step (d) comprises:
discharging the compressed gas supplied to the first main nozzle and the second main nozzle of the mounting head with different pressures.

20. The method of claim 19, wherein
in the step (e), the mounting head is transported in a direction perpendicular to the first wall member and the second wall member, and
in the step (d), the compressed gas is discharged while maintaining a pressure of a nozzle, from among the first main nozzle and the second main nozzle, located in a front portion of a direction in which the mounting head is transported to be greater than a pressure of a nozzle, from among the first main nozzle and the second main nozzle, located in a rear portion of the direction in which the mounting head is transported.
